(19) United States
(12) Patent Application Publication
(10) Pub. No.: US 2013/0137037 A1
(43) Pub. Date: May 30, 2013

(54) Silicon Compound, Condensation Product, Resist Compostion and Pattern Formation Method

(71) Applicant: Central Glass Company, Limited, Ube-shi (JP)

(72) Inventors: Kazuhiro YAMANAKA, Tokyo (JP); Tsuyoshi Ogawa, Iruma-gun (JP)

(73) Assignee: Central Glass Company, Limited, Ube-shi (JP)

(21) Appl. No.: 13/678,283

(22) Filed: Nov. 15, 2012

(30) Foreign Application Priority Data
Nov. 22, 2011 (JP) 2011-254872
Oct. 29, 2012 (JP) 2012-238210

(51) Int. Cl. G03F 7/075; G03F 7/20; C07F 7/18

(52) U.S. Cl. CPC G03F 7/0755; C07F 7/1836; G03F 7/20
USPC 430/283.1; 556/420; 556/428; 556/419; 430/281.1; 430/325

(57) ABSTRACT

A silicon compound according to the present invention is represented by the general formula (1). This silicon compound can be easily synthesized by using a hydrolysable silicon compound such as alkoxysilane and has, in its molecule, a hydrolysable group e.g. alkoxy group and a photoacid generating group capable of being dissociated to generate an acid by irradiation with a high-energy ray.

R¹ₙAₘSiB₄₋₍ₙ₊ₘ₎ (1)

where R¹ is each independently a hydrogen atom, a C₁-C₂₀ straight or C₃-C₂₀ branched or cyclic hydrocarbon group; a carbon atom of the hydrocarbon group may be replaced by an oxygen atom; and the hydrocarbon group may contain a fluorine atom; A is an acid decomposable group; B is a hydrolysable group; n is an integer of 0 to 2; m is an integer of 1 to 3; and n+m is an integer of 1 to 3.

### FIELD OF THE INVENTION

The present invention relates to a novel silicon compound, a condensation product obtained by hydrolysis and condensation of the silicon compound, a resist composition containing the condensation product and a pattern formation method using the resist composition.

### BACKGROUND OF THE INVENTION

There has been an advance toward fine resist patterning by lithography for high integration of LSI devices. The lithography is a technique of applying a photosensitive material (photoresist, sometimes simply referred to as “resist”) to a surface of a substrate, exposing the resist into a desired pattern through a photomask or reticle, developing the exposed portion of the resist with a developer and thereby forming a pattern of the resist (sometimes simply referred to as “pattern”) on the substrate due to a difference in developer solubility between the exposed and unexposed portions of the resist.

The application of shorter-wavelength exposure light sources is one factor behind the advance toward very fine patterning. For example, the conversion from a mercury-lamp that emits an ultraviolet i-ray (wavelength: 365 nm) to a krypton fluoride (abbreviated as “KrF”) excimer laser that emits a laser ray of 248 nm wavelength leads to a processing accuracy of 0.25 μm or smaller so as to enable mass production of 64 M-bit dynamic random access memory (abbreviated as “DRAM”).

The application of lithography using an argon fluoride (abbreviated as “ArF”) excimer laser of 193 nm wavelength has also been studied for production of DRAM with an integration of 256 M-bit, 512 M-bit, 1 G-bit or higher level. In particular, the combination of ArF laser lithography process with a high numerical aperture lens (NA>0.9) is being studied for production of 65-nm node (junction) devices.

For production of next 45-nm node devices, a F₂ laser of 157 nm wavelength is considered as a candidate light source for use in lithography processes. However, the application of F₂ laser lithography has been postponed due to many problems such as increase in scanner cost, change of optical system and low resist etch resistance.

As an alternative to the F₂ laser lithography, liquid immersion lithography using an ArF excimer laser as a light source has been proposed. The liquid immersion lithography is a lithography process in which exposure is performed under a condition that a liquid is filled in a space between a lens of an exposure device and a substrate with a resist film. For example, the exposure can be preformed with the use of an ArF excimer laser as a light source and water as the liquid filled between the lens and the substrate. The refractive index of water relative to an ArF excimer laser ray (wavelength: 193 nm) is 1.44, whereas the refractive index of air is 1. The incident angle of the exposure light to the substrate is greater with the use of water than with the use of air. This leads to a numerical aperture of 1 or higher for improvement in pattern resolution.

Further, lithography using an extreme ultraviolet (abbreviated as “EUV”) light is being studied for design rules of 45-nm or smaller pitch node devices.

As resists suitable for exposure by such short-wavelength light sources, “chemically amplified resist materials” are put into use. The chemically amplified resist material contains a photoacid generator capable of generating an acid by exposure to provide an exposed portion in which resist polymer is decomposed by the generated acid and an unexposed portion and forms a pattern due a difference in developer solubility between the exposed and unexposed portions of the resist.

For the fine patterning of chemically amplified resists, it has become important that the resist containing the resist resin decomposed under the action of the acid generated by exposure shows equal solubility in a developer, that is, the developer solubility of the resist film in the developer is uniform. In general, the chemically amplified resist needs to be subjected to treatment (post exposure bake; abbreviated as “PEB”) by, after generating the acid from the photoacid generator in the resist film, applying heat to the resist film and thereby distributing the generated acid through the resist. The distribution of the acid during PEB is one factor that makes very fine patterning difficult. It has thus been studied to introduce a functional group (called photoacid generating group) capable of generating an acid by exposure into a resist resin by synthesizing the resist resin with the use of a polymerizable monomer having such a photoacid generating group in order to decrease the length of distribution of the acid in the resist film and achieve very fine patterning.

Most of these resist resins are obtained by polymerization of polymerizable methacrylate monomers having photoacid generating groups in their side chains. There are a few examples of silicon compounds with photoacid generating groups.

Some examples of silicon compounds with photoacid generating groups are herein discussed as follows. For example, Patent Document 1 discloses a silicon-containing sulfonium salt having a sulfonium cation and a siloxane in a repeating unit thereof as a sulfonate polymer having a silicon atom in its main chain and a photoresist composition containing the same. As a counter ion of the sulfonium cation, there can be used BF₄, AsF₆, SbF₆, PF₆ and CF₃SO₃. In this photoresist composition, the silicon-containing sulfonium salt generates an acid by light irradiation and converts to a low-molecular-weight form by decomposition of the main chain so as to cause a significant change in the solubility of the sulfonium salt in a solvent.

It is described that the photoresist composition of Patent Document 1 shows good oxygen plasma resistance in the presence of silicon in the sulfonium salt compound. However, it is not described that the photoresist composition of Patent Document 1 can be formed into a very fine pattern by uniformization of the resist solubility.

Patent Document 2 discloses a photoactive compound having a photoacid generating group in a side chain of a cyclic polysiloxane. The photoactive compound of Patent Document 2 is however complicated in structure and difficult to synthesize in comparison with a silicon compound obtained as a condensation product by hydrolysis and condensation of an ordinary alkoxysilane.

In either case, there has not yet established any method for efficiently introducing a photoacid generating group to a silicon resin with good heat resistance, transparency, adhesion and oxygen plasma resistance.

Patent Documents 3 to 12 disclose resists with polymerizable methacrylate monomers and photoacid generating groups and photoacid generating groups.

More specifically, Patent Document 3 discloses an unsaturated onium salt and a production method thereof. Patent Document 4 discloses a photosensitive resin composition containing a polymer with a repeating unit of onium salt structure. Patent Document 5 discloses a N-sulfonyloxyimide compound and a radiation-sensitive resin composition using the same. Patent Document 6 discloses a 2-(alkylcarbonyloxy)-1,1-difluoroethanesulfonic acid salt and a production method thereof. Patent Document 7 discloses a polymerizable sulfonic acid onium salt and resin. Patent Document 8 discloses a novel compound, a polymer and a radiation-sensitive resin composition. Patent Document 9 discloses a novel sulfonic acid salt and a derivative thereof, a photoacid generator and a production method of the sulfonic acid salt. Patent Document 10 discloses a fluorine-containing compound, a fluorine-containing polymer compound, a negative resist composition and a pattern formation method using the same. Patent Document 11 discloses a sulfonium compound for production of an acid generator in a chemically amplified resist composition. Patent Document 12 discloses a salt of novel fluorine-containing carbanion structure and a derivative thereof, a photoacid generator, a resist material using the same and a pattern formation method.

### PRIOR ART DOCUMENTS

### Patent Documents

Patent Document 1: Japanese Laid-Open Patent Publication No. H06-342209
Patent Document 2: Japanese Laid-Open Patent Publication No. 2010-209259
Patent Document 3: Japanese Laid-Open Patent Publication No. H04-230645
Patent Document 4: Japanese Laid-Open Patent Publication No. 2005-084365
Patent Document 5: Japanese Laid-Open Patent Publication No. 2001-199955
Patent Document 6: Japanese Laid-Open Patent Publication No. 2009-091351
Patent Document 7: International Application Publication No. WO 2008/056795
Patent Document 8: International Application Publication No. WO 2006/121096
Patent Document 9: Japanese Laid-Open Patent Publication No. 2010-018573
Patent Document 10: Japanese Laid-Open Patent Publication No. 2009-029802
Patent Document 11: Japanese Laid-Open Patent Publication No. 2008-127367
Patent Document 12: Japanese Laid-Open Patent Publication No. 2009-242391

### SUMMARY OF THE INVENTION

In the case of introducing a photoacid generating group to a silicon resin obtained from an ordinary alkoxysilane, it is conceivable to adopt a hydrosilylation process as described in Patent Document 2. The hydrosilylation process needs to use a platinum catalyst. It is difficult to, after the reaction, completely remove the platinum catalyst from the silicon resin or the alkoxysilane used as the raw material of the silicon resin. Further, the use of the platinum catalyst is unfavorable in the semiconductor field where the contamination of metal impurities becomes a problem.

As mentioned above, there has not been established any method for efficiently introducing a photoacid generating group into a silicon resin with good heat resistance, transparency, adhesion and oxygen plasma resistance.

It is accordingly an object of the present invention to provide a silicon compound that can be readily produced using a hydrolysable silicon compound such as alkoxysilane as a raw material and has, in its molecule, a hydrolysable group e.g. alkoxy group and a photoacid generating group capable of being decomposed to form an acid by irradiation with a high-energy ray.

Namely, the present invention provides a novel hydrolysable silicon compound with a photoacid generating group as set forth below.

[Inventive Aspect 1]

A silicon compound of the general formula (1):

R¹ₙAₘSiB₄₋₍ₙ₊ₘ₎ (1)

where R¹ is each independently a hydrogen atom, a C₁-C₂₀ straight or C₃-C₂₀ branched or cyclic hydrocarbon group; a carbon atom of the hydrocarbon group may be replaced by an oxygen atom; and the hydrocarbon group may contain a fluorine atom; A is an acid decomposable group; B is a hydrolysable group; n is an integer of 0 to 2; m is an integer of 1 to 3; and n+m is an integer of 1 to 3.

Specific examples of B are a chlorine atom, a methoxy group, an ethoxy group and an isopropoxy group. Each of R¹, A and B is bonded to Si (silicon atom).

[Inventive Aspect 2]

The silicon compound according to Inventive Aspect 1, wherein at least one of A is a group of the general formula (2-1):

-D-E^{⊕} (2-1)

where D is a single bond or a divalent organic group which may have an ester bond, an urethane bond or an amide bond; and E is a group of the general formula (3-1), a group of the general formula (3-2), a group of the general formula (3-3) or a group of the general formula (3-4):

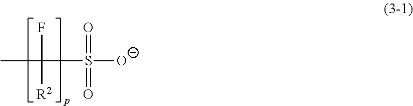

where R² is each independently a fluorine atom or a C₁-C₁₀ fluorine-containing alkyl group; and p is an integer of 1 to 2,

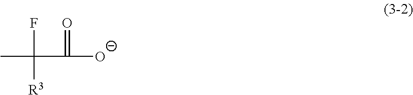

where R³ is each independently a fluorine atom or a C₁-C₁₀ fluorine-containing alkyl group,

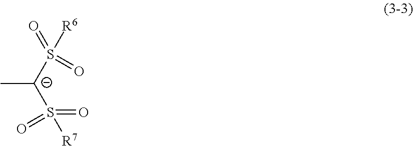

where R⁶ and R⁷ are each independently a C₁-C₁₀ fluorine-containing alkyl group,

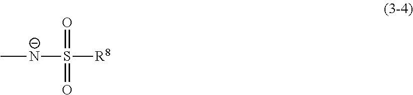

where R⁸ is a C₁-C₁₀ fluorine-containing alkyl group.

[Inventive Aspect 3]

The silicon compound according to Inventive Aspect 1 or 2, wherein at least one of A is a group of the formula (2-1):

-D-E^{⊖} (2-1)

where D is a single bond or a divalent organic group which may have an ester bond, an urethane bond or an amide bond; and
E is a group of the formula (3-5), a group of the formula (3-6), a group of the formula (3-7) or a group of the formula (3-8):

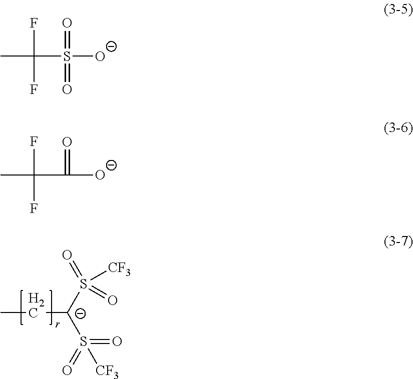

where r is an integer of 1 to 3

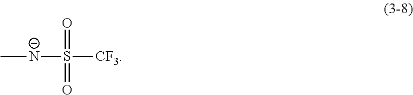

[Inventive Aspect 4]

The silicon compound according to Inventive Aspect 1, wherein at least one of A is a group of the general formula (2-2):

-D-E^{⊖}G^{⊕} (2-2)

where D is a single bond or a divalent group which may have an ester bond, an urethane bond or an amide group;
E⁻ is a group of the general formula (3-1), a group of the general formula (3-2), a group of the general formula (3-3), a group of the general formula (3-4), a group of the formula (3-5), a group of the formula (3-6), a group of the formula (3-7) or a group of the formula (3-8):

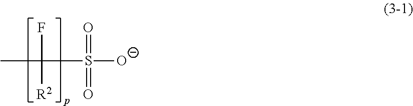

where R² is each independently a fluorine atom or a C₁-C₁₀ fluorine-containing alkyl group; and p is an integer of 1 to 2;

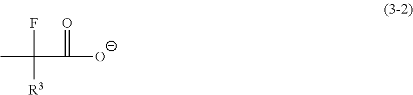

where R³ is a fluorine atom or a C₁-C₁₀ fluorine-containing alkyl group;

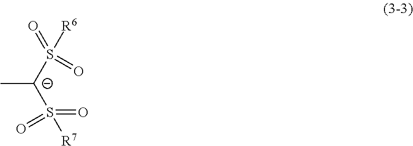

where R⁶ and R⁷ are each independently a C₁-C₁₀ fluorine-containing alkyl group;

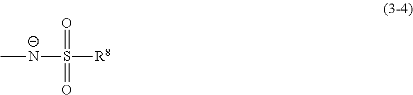

where R⁸ is a C₁-C₁₀ fluorine-containing alkyl group;

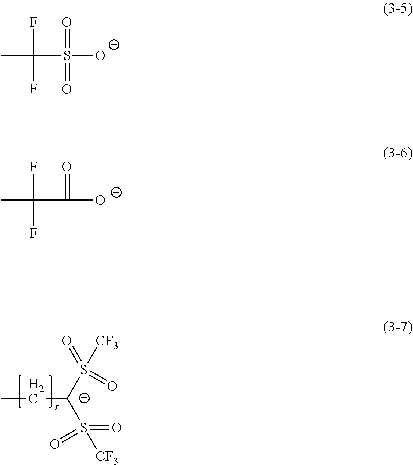

where r is an integer of 1 to 3

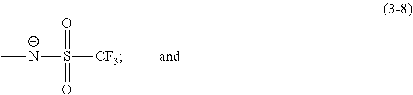

G⁺ is a sulfonium cation of the formula (4-1) or a iodonium cation of the formula (4-2);

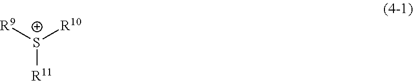

where R⁹, R¹⁰ and R¹¹ are each independently a hydrocarbon group selected from the group consisting of a C₁-C₂₀ straight or C₃-C₂₀ branched or cyclic alkyl group, a C₁-C₂₀ straight or C₃-C₂₀ branched or cyclic alkenyl group, a C₆-C₂₀ aryl group and a C₇-C₂₀ aralkyl group; a carbon atom of the hydrocarbon group may be replaced by an oxygen atom; and two or more of R⁹, R¹⁰ and R¹¹ may be bonded together to form a ring structure,

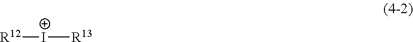

where R¹² and R¹³ are each independently a hydrocarbon group selected from the group consisting of a C₁-C₂₀ straight or C₃-C₂₀ branched or cyclic alkyl group, a C₁-C₂₀ straight or C₃-C₂₀ branched or cyclic alkenyl group, a C₆-C₂₀ aryl group and a C₇-C₂₀ aralkyl group; a carbon atom of the hydrocarbon group may be replaced by an oxygen atom; and R¹² and R¹³ may be bonded together to form a ring structure.

[Inventive Aspect 5]

The silicon compound according to Inventive Aspect 1, wherein at least one of A is a group of the general formula (5):

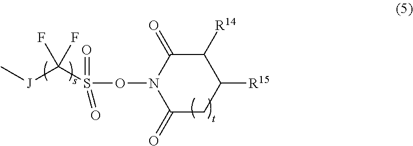

where R¹⁴ and R¹⁵ are each independently a hydrogen atom or a C₁-C₁₀ straight, C₃-C₁₀ branched or C₃-C₁₀ cyclic hydrocarbon group; a carbon atom of the hydrocarbon group may be replaced by an oxygen atom; R¹⁴ and R¹⁵ may be bonded together to form a ring structure; J is a single bond or a divalent group which may have an ester bond, an urethane bond or an amide group; s is an integer of 1 to 2; and t is an integer of 0 to 2.

[Inventive Aspect 6]

The silicon compound according to Inventive Aspect 1, wherein at least one of A is a group of the general formula (6):

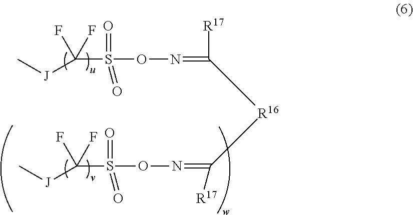

where R¹⁶ is a single bond or a hydrocarbon group selected from the group consisting of a C₁-C₂₀ alkylene group and a C₆-C₁₅ arylene group; a carbon atom of the hydrocarbon group may be replaced by an oxygen atom; R¹⁷ is each independently a methyl group, a trifluoromethyl group, a perfluoroethyl group, a perfluoropropyl group, a 5H-perfluoropentyl group, a 6H-perfluorohexyl group, a cyano group or a nitro group; u is an integer of 1 to 2; v is an integer of 1 to 2; w is 0 or 1; when w is 0, R′⁷ may be bonded together to form a ring structure; and J is a single bond or a divalent organic group which may have an ester bond, an urethane bond or an amide bond.

The present invention also provides a condensation product by hydrolysis and condensation of the silicon compound according to Inventive Aspects 1 to 6.

[Inventive Aspect 7]

A condensation product obtained by condensation of the silicon compound according to Inventive Aspects 1 to 6.

Further, the present invention provides a resist composition for use in photolithography by addition of a solvent to the condensation product according to Inventive Aspect 6. The resist composition according to the present invention can be applied as a resist solution to a glass substrate or silicon substrate. As the solvent, there can be used e.g. propylene glycol monomethyl ether acetate (abbreviated as “PGMEA”), propylene glycol monomethyl ether, cyclohexanone, γ-butyrolactone, ethyl lactate, methyl ethyl ketone, methyl isobutyl ketone, N,N-dimethylformamide or N-methylpyrrolidone.

[Inventive Aspect 8]

A composition comprising the condensation product according to Inventive Aspect 7 and a solvent.

[Inventive Aspect 9]

A pattern formation method, comprising:

a first step of forming a film by applying the composition according to Inventive Aspect 8 to a substrate and drying the applied composition;

a second step of exposing the film to a high-energy ray through a photomask of predetermined pattern; and

a third step of forming a resist pattern by dissolving an unexposed portion of the film with a developer and thereby transferring the pattern of the photomask to the film.

The silicon compound with the photoacid generating group and the hydrolysable group (photoacid generating group-containing alkoxysilane) according to the present invention can be converted to a condensation product (silicon resin) by hydrolytic polycondensation thereof alone or by copolymerization with any other alkoxysilane or alkoxysilanes. The thus-obtained condensation product is capable of sensing a high-energy ray such as an ultraviolet ray e.g. far-ultraviolet ray or extreme-ultraviolet ray (EUV), an electron beam, an X-ray, an excimer laser, a γ-ray or a synchrotron radiation ray obtained from a synchrotron as one type of circular accelerator and thereby generating a fluorine-containing sulfonic acid, fluorine-containing carboxylic acid, fluorine-containing methide acid or fluorine-containing sulfone amide of very high acidity.

The silicon compound according to the present invention and the product of hydrolysis and condensation of the silicon compound can be produced from an easy-to-get alkoxysilane as a raw material without the use of a metal catalyst and thus can suitably be used as semiconductor and display materials where high insulating properties are required. The condensation product contains in its structure the photoacid generating group and, when used as a resist, allows uniform distribution of the photoacid generating moiety in the resulting resist film as compared to a conventional resist containing an addition-type photoacid generator. Thus, the resist can be obtained with high sensitivity and pattern resolution and enable fine patterning.

The silicon compound according to the present invention and the condensation product obtained therefrom can also be used in place of a conventional resist in which a resin with a photoacid generating group is added to a resin with no photoacid generating group, so as to form a finer pattern due to less distribution of the acid in the resin during exposure in lithography process. As not only the hydrolysable group e.g. alkoxy group but also the photoacid generating group are present in the same molecule, the acid decomposed from the photoacid generating group by irradiation with high-energy ray becomes less distributed in the resin so that the silicon compound or condensation product can form a finer pattern as compared to a conventional resist in which a photoacid generator is separately added to a resin.

### DESCRIPTION OF THE EMBODIMENTS

1. Silicon Compound of General Formula (1)

First, a silicon compound according to the present invention will be described below. The silicon compound according to the present invention is represented by the general formula (1).

R¹ₙAₘSiB₄₋₍ₙ₊ₘ₎ (1)

In the formula (1), R¹ is each independently a hydrogen atom or a C₁-C₂₀ straight or C₃-C₂₀ branched or cyclic hydrocarbon group; a carbon atom of the hydrocarbon group may be replaced by an oxygen atom; the hydrocarbon group may contain a fluorine atom; A is an acid decomposable group; B is a hydrolysable group; n is an integer of 1 to 2; m is an integer of 1 to 3; and n+m is an integer of 1 to 3.

Specific examples of R¹ are hydrogen, methyl, ethyl, n-propyl, iso-propyl, n-butyl, sec-butyl, phenyl and fluoroalkyl such as trifluoromethyl, pentafluoroethyl and 3,3,3-trifluoropropyl.

Specific examples of the hydrolysable group (B) are chlorine, methoxy, ethoxy and isopropoxy.

2. Group (A) in Silicon Compound of General Formula (1)

The photoacid group (A) contained in the silicon compound of the general formula (1) will be explained below. The group (A) has the capability of sensing a high-energy ray such as an ultraviolet ray e.g. far-ultraviolet ray or extreme-ultraviolet ray (EUV), an electron beam, an X-ray, an excimer laser, a γ-ray or a synchrotron radiation ray obtained from a synchrotron as one type of circular accelerator and thereby generating a fluorine-containing sulfonic acid, fluorine-containing carboxylic acid, fluorine-containing methide acid or fluorine-containing sulfone amide of very high acidity.

2.1 Case of Containing Anion as group (A) in Silicon Compound of General Formula (1)

The following explanation will be given on the case of containing an anion as the group (A) in the silicon compound of the general formula (1). In this case, the group (A) is a group of the general formula (2-1).

-D-E^{⊖} (2-1)

The group of the general formula (2-1) is converted to a sulfonic acid, a carboxylic acid, a methide acid or a sulfonamide by irradiation with the high-energy ray.

In the formula (2-1), D is a single bond or a divalent organic group which may have an ester bond, an urethane bond or an amide bond.

On the other hand, E is a group of any of the general formulas (3-1) to (3-4) or any of the formulas (3-5) to (3-8).

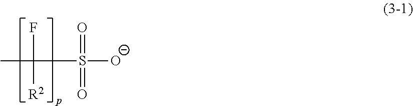

In the formula (3-1), R² is each independently a fluorine atom or a C₁-C₁₀ fluorine-containing alkyl group; and p is an integer of 1 to 2.

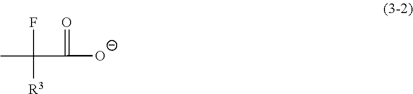

In the formula (3-2), R³ is a fluorine atom or a C₁-C₁₀ fluorine-containing alkyl group.

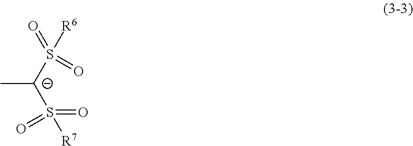

In the formula (3-3), R⁶ and R⁷ are each independently a C₁-C₁₀ fluorine-containing alkyl group.

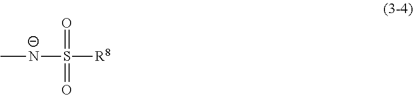

In the formula (3-4), R⁸ is a C₁-C₁₀ fluorine-containing alkyl group.

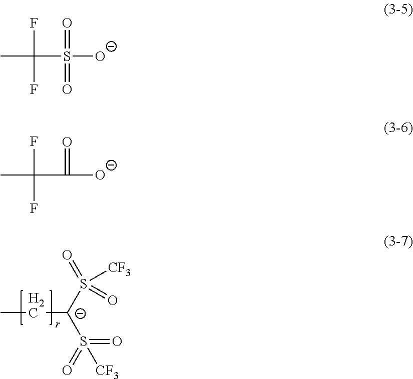

In the formula (3-7), r is an integer of 1 to 3.

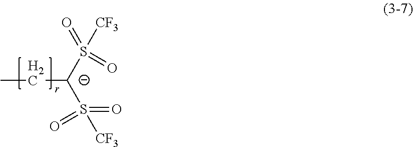

2.2 Case of Containing Salt as Group (A) in Silicon Compound of General Formula (1)

The following explanation will be given on the case of containing a salt as the group (A) in the silicon compound of the general formula (1). In this case, the group (A) is a polymerizable fluorine-containing sulfonic acid onium salt formed by ionic bond of a cation G⁺, more specifically a sulfonium cation of the general formula (4-1) or a iodonium cation of the general formula (4-2), to the group of the general formula (2-1).

Namely, the group (A) is a group in which is G′ bonded by ionic bond to E of the general formula (2-1) and thus is represented by the general formula (2-2).

-D-E^{⊖}G^{⊕} (2-2)

In the formula (2-2), D is a single bond or a divalent group which may have an ester bond, an urethane bond or an amide group.

As indicated in the following reaction scheme, G⁺ is eliminated from the group of the general formula (2-2) by irradiation with the high-energy ray so that the group of the general formula (2-2) is converted to a sulfonic acid, a carboxylic acid, a methide acid or a sulfonamide.

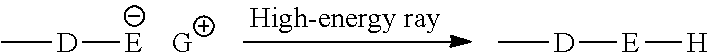

As mentioned above, G⁺ is a sulfonium cation of the general formula (4-1) or a iodonium cation of the general formula (4-2).

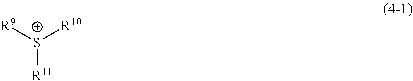

In the formula (4-1), R⁹, R¹⁰ and R¹¹ are each independently a hydrocarbon group selected from the group consisting of a C₁-C₂₀ straight or C₃-C₂₀ branched or cyclic alkyl group, a C₁-C₂₀ straight or C₃-C₂₀ branched or cyclic alkenyl group, a C₆-C₂₀ aryl group and a C₇-C₂₀ aralkyl group; a carbon atom of the hydrocarbon group may be replaced by an oxygen atom; and two or more of R⁹, R¹⁰ and R¹¹ may be bonded together to form a ring structure.

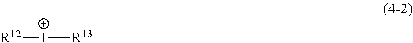

In the formula (4-2), R¹² and R¹³ are each independently a hydrocarbon group selected from the group consisting of a C₁-C₂₀ straight or C₃-C₂₀ branched or cyclic alkyl group, a C₁-C₂₀ straight or C₃-C₂₀ branched or cyclic alkenyl group, a C₆-C₂₀ aryl group and a C₇-C₂₀ aralkyl group; a carbon atom of the hydrocarbon group may be replaced by an oxygen atom; and R¹² and R¹³ may be bonded together to form a ring structure.

2.2.1 Sulfonium Cation of General Formula (4-1)

The sulfonium cation of the formula (4-1) usable as the cation G′ in the silicon compound will be explained in detail below.

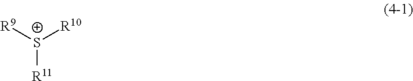

In the formula (4-1), R⁹, R¹⁰ and R¹¹ are each independently a hydrocarbon group selected from the group consisting of a C₁-C₂₀ straight or C₃-C₂₀ branched or cyclic alkyl group, a C₁-C₂₀ straight or C₃-C₂₀ branched or cyclic alkenyl group, a C₆-C₂₀ aryl group and a C₇-C₂₀ aralkyl group; a carbon atom of the hydrocarbon group may be replaced by an oxygen atom; and two or more of R⁹, R¹⁰ and R¹¹ may be bonded together to form a ring structure.

As R⁹, R¹⁰ and R¹¹, examples of the alkyl group are methyl, ethyl, n-propyl, isopropyl, cyclopropyl, n-butyl, sec-butyl, isobutyl, tert-butyl, n-pentyl, cyclopentyl, n-hexyl, n-heptyl, 2-ethylhexyl, cyclohexyl, cycloheptyl, 4-methylcyclohexyl, cyclohexylmethyl, n-octyl, n-decyl, 1-adamantyl, 2-adamantyl, bicyclo[2.2.1]heptene-2-yl, 1-adamantanemethyl and 2-adamantanemethyl.

Examples of the alkenyl group are vinyl, allyl, propenyl, butenyl, hexenyl and cyclohexenyl. There can also be a C₁-C₂₀ straight, branched or cyclic oxoalkyl group which may have a substituent. Examples of the oxoalkyl group are 2-oxocyclopentyl, 2-oxocyclohexyl, 2-oxopropyl, 2-oxoethyl, 2-cyclopentyl-2-oxoethyl, 2-cyclohexyl-2-oxoethyl and 2-(4-methylcyclohexyl)-2-oxoethyl. Examples of the aryl group are: phenyl; naphthyl; thienyl; alkoxylphenyl groups such as p-methoxyphenyl, m-methoxyphenyl, o-methoxyphenyl, p-ethoxypenyl, p-tert-butoxyphenyl and m-tert-butoxyphenyl; alkylphenyl groups such as 2-methylphenyl, 3-methylphenyl, 4-methylphenyl and ethylphenyl; alkylnaphthyl groups such as methylnaphthyl and ethylnaphthyl; dialkylnaphthyl groups such as diethylnaphthyl; and dialkoxynaphthyl groups such as dimethoxynaphthyl and diethoxynaphthyl. Examples of the aralkyl group are benzyl, 1-phenylethyl and 2-phenylethyl. Further, there can be used an aryloxoalkyl group such as 2-aryl-2-oxoethyl groups such as 2-phenyl-2-oxoethyl, 2-(1-naphthyl)-2-oxoethyl and 2-(2-naphthyl)-2-oxoethyl. In the case where two or more of R⁹, R¹⁰ and R¹¹ are bonded to each other to form a ring with the sulfur atom, these groups can be divalent groups such as 1,4-butylene and 3-oxa-1,5-penthylene. Aryl groups with polymerizable substituents such as acryloyloxy and methacryloyloxy, including 4-(acryloyloxy)phenyl, 4-(methacryloyloxy)phenyl, 4-vinyloxyphenyl and 4-vinylphenyl, are also usable.

Specific examples of the sulfonium cation of the general formula (4-1) are triphenylsulfonium, (4-tert-butylphenyl)diphenylsulfonium, bis(4-tert-butylphenyl)phenylsulfonium, tris(4-tert-butylphenyl)sulfonium, (3-tert-butylphenyl)diphenylsulfonium, bis(3-tert-butylphenyl)phenylsulfonium, tris(3-tert-butylphenyl)sulfonium, (3,4-di-tert-butylphenyl)diphenylsulfonium, bis(3,4-di-tert-butylphenyl)phenylsulfonium, tris(3,4-di-tert-butylphenyl)sulfonium, (4-tert-butoxyphenyl)diphenylsulfonium, bis(4-tert-butoxyphenyl)phenylsulfonium, tris(4-tert-butoxyphenyl)sulfonium, (3-tert-butoxyphenyl)diphenylsulfonium, bis(3-tert-butoxyphenyl)phenylsulfonium, tris(3-tert-butoxyphenyl)sulfonium, (3,4-di-tert-butoxyphenyl)diphenylsulfonium, bis(3,4-di-tert-butoxyphenyl)phenylsulfonium, tris(3,4-di-tert-butoxyphenyl)sulfonium, diphenyl(4-thiophenoxyphenyl)sulfonium, (4-tert-butoxycarbonylmethyloxyphenyl)diphenylsulfonium, tris(4-tert-butoxycarbonylmethyloxyphenyl)diphenylsulfonium, (4-tert-butoxyphenyl)bis(4-dimethylaminophenyl)sulfonium, tris(4-dimethylaminophenyl)sulfonium, 2-naphthyldiphenylsulfonium, dimethyl(2-naphthyl)sulfonium, (4-hydroxyphenyl)dimethylsulfonium, (4-methoxyphenyl)dimethylsulfonium, trimethylsulfonium, (2-oxocyclohexyl)cyclohexylmethylsulfonium, trinaphthylsulfonium, tribenzylsulfonium, diphenylmethylsulfonium, dimethylphenylsulfonium, 2-oxo-2-phenylethylthiacyclopentanium, diphenyl 2-thienylsulfonium, 4-n-butoxynaphthyl-1-thiacyclopentanium, 2-n-butoxynaphthyl-1-thiacyclopentanium, 4-methoxynaphthyl-1-thiacyclopentanium and 2-methoxynaphthyl-1-thiacyclopentanium. Among others, preferred are triphenylsulfonium, (4-tert-butylphenyl)diphenylsulfonium, (4-tert-butoxyphenyl)diphenylsulfonium, tris(4-tert-butylphenyl)sulfonium and (4-tert-butoxycarbonylmethyloxyphenyl)diphenylsulfonium.

Further, 4-(methacryloyloxy)phenyldiphenylsulfonium, 4-(acryloyloxy)phenyldiphenylsulfonium, 4-(methacryloyloxy)phenyldimethylsulfonium and 4-(acryloyloxy)phenyldimethylsulfonium are also specific examples of the sulfonium cation of the general formula (a). There can also be used polymerizable sulfonium cations disclosed in Patent Documents 3 and 4.

2.2.2 Iodonium Cation of General Formula (4-2)

Next, the iodonium cation of the general formula (4-2) usable as the cation G′ in the silicon compound will be explained in detail below.

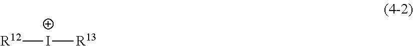

In the formula (4-2), R¹² and R¹³ are each independently a hydrocarbon group selected from the group consisting of a C₁-C₂₀ straight or C₃-C₂₀ branched or cyclic alkyl group, a C₁-C₂₀ straight or C₃-C₂₀ branched or cyclic alkenyl group, a C₆-C₂₀ aryl group and a C₇-C₂₀ aralkyl group; a carbon atom of the hydrocarbon group may be replaced by an oxygen atom; and R¹² and R¹³ may be bonded together to form a ring structure.

Examples of R¹² and R¹³ are the same as those of R⁹, R¹⁰ and R¹¹ indicated above.

Specific examples of the iodonium cation of the general formula (4-2) are bis(4-methylphenyl)iodonium, bis(4-ethylphenyl)iodonium, bis(4-tert-butylphenyl)iodonium, bis(4-(1,1-dimethylpropyl)phenyl)iodonium, (4-methoxyphenyl)phenyliodonium, (4-tert-butoxyphenyl)phenyliodonium, (4-acryloyloxy)phenylphenyliodonium and (4-methacryloyloxy)phenylphenyliodonium. Among others, bis(4-tert-butylphenyl)iodonium is preferred.

2.3 Case of Containing Group of General Formula (5) or Group of General Formula (6) as Group (A) in Silicon Compound of General Formula (1)

It is feasible to contain a fluorine-containing N-sulfonyloxyimide group of the general formula (5) or a fluorine-containing oxime group of the general formula (6) as the group (A) in the silicon compound of the general formula (1). In this case, the silicon compound can be used as a monomer or converted to a resin by hydrolytic polycondensation thereof alone or by copolymerization with any other alkoxysilane or alkoxysilane, and has the capability of generating a fluorine-containing sulfonic acid of very high acidity by irradiation with the high-energy ray such as ultraviolet ray, far-ultraviolet ray, extreme-ultraviolet ray (EUV), electron beam, X-ray, excimer laser, γ-ray or synchrotron radiation ray.

2.3.1 Case of Containing Group of General Formula (5) as Group (A) in Silicon Compound of General Formula (1)

The following explanation will be given on the case where the group (A) is the group of the general formula (5) in the silicon compound of the general formula (1).

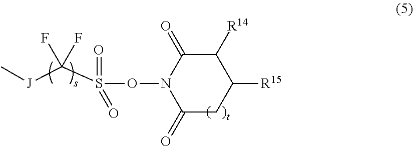

In the formula (5), R¹⁴ and R¹⁵ are each independently a hydrogen atom or a C₁-C₁₀ straight, C₃-C₁₀ branched or C₃-C₁₀ cyclic hydrocarbon group; a carbon atom of the hydrocarbon group may be replaced by an oxygen atom; R¹⁴ and R¹⁵ may be bonded together to form a ring structure; J is a single bond or a divalent group which may have an ester bond, an urethane bond or an amide group; s is an integer of 1 to 2; and t is an integer of 0 to 2.

The ring structure formed by R¹⁴ and R¹⁵ can be an aliphatic ring, an aromatic ring or a heterocyclic ring. The following are preferred specific examples of the group of the general formula (15).

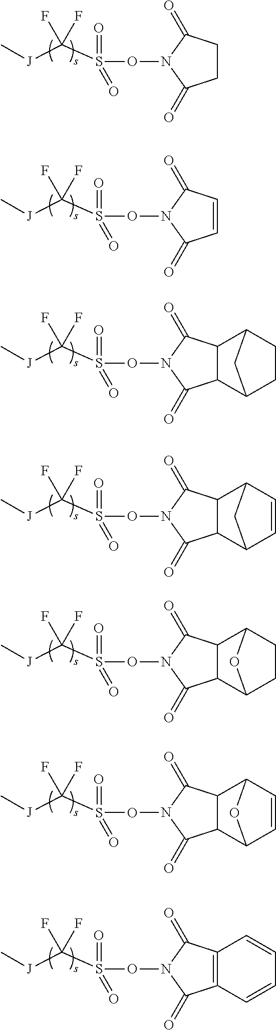

[Synthesis of Precursor Alcohol]

An alcohol compound of the following general formula (5A) is an example of a precursor alcohol for introduction of the group of the general formula (5) as the group (A) into the silicon compound of the general formula (1).

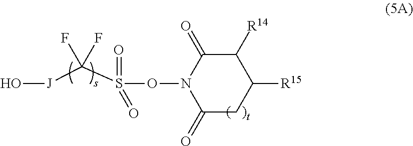

In the formula (5A), R¹⁴ and R¹⁵ are each independently a hydrogen atom or a C₁-C₁₀ straight, C₃-C₁₀ branched or C₃-C₁₀ cyclic hydrocarbon group; a carbon atom of the hydrocarbon group may be replaced by an oxygen atom; R¹⁴ and R¹⁵ may be bonded together to form a ring structure; J is a single bond or a divalent group which may have an ester bond, an urethane bond or an amide group; s is an integer of 1 to 2; and t is an integer of 0 to 2.

By way of example, the process for synthesis of a precursor alcohol of the general formula (5B), which is one example of the alcohol compound of the general formula (5A), will be explained below. In this synthesis process, the precursor alcohol is synthesized from a hydroxysulfonate and a N-hydroxydicarboxylmide as described in Patent Document 5. The following reaction scheme shows synthesis of the alcohol of the general formula (5B) as one synthesis example. It is however noted that the precursor alcohol is not limited to the alcohol of the general formula (5B).

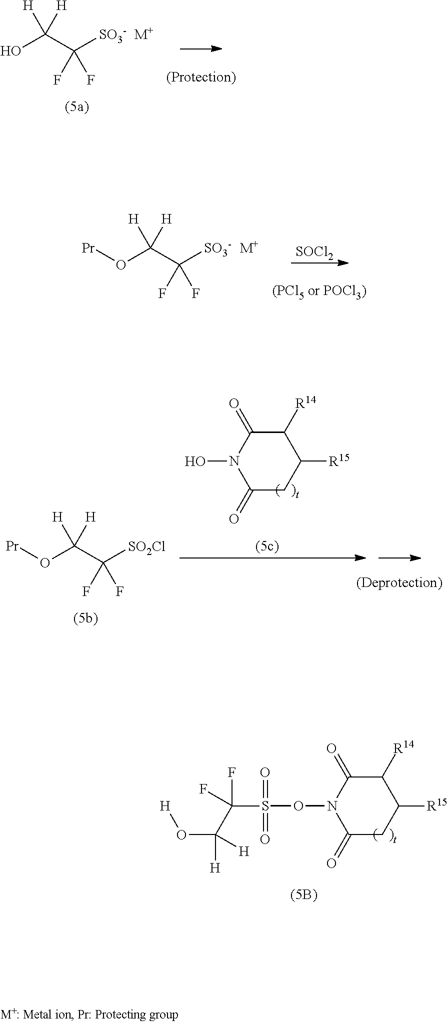

As shown in the reaction scheme, a hydroxyfluoroalkanesulfonic acid onium salt of the formula (5a) as the hydroxysulfonate is subjected to hydroxylprotection by reaction with trimethyl silyl chloride, acetyl chloride etc., and then, converted to sulfonyl chloride of the formula (5b) by reaction with phosphorus pentachloride, thionyl chloride, phosphorus oxychloride etc.

As the hydroxyfluoroalkanesulfonic acid onium salt, there can be used not only the salt of the formula (5a) but also other salts such as 2-hydroxy-1,1-difluoroethanesulfonic acid triphenylsulfonium, 4-hydroxy-1,1,2,2-tetrafluorobutanesulfonic acid triphenylsulfonium, 5-hydroxy-1,1,2,2-tetrafluoropentanesulfonic acid triphenylsulfonium and 6-hydroxy-1,1,2,2-tetrafluorohexanesulfonic acid triphenylsulfonium. These compounds can be synthesized as described in Patent Documents 5 to 9.

Subsequently, a N-hydroxydicarboxylmide of the following general formula (5c), which is synthesized from a dicarboxylic acid and a hydroxylamine, is reacted with the sulfonyl chloride of the formula (5b). The resulting reaction product is subjected to deprotection by reaction in a solvent such as tetrahydrofuran (abbreviated as “THF”) or dichloromethane under basic conditions or in a basic solvent such as triethylamine or pyridine, and then, by reaction with a Lewis acid etc. With this, the target fluorine-containing N-sulfonyloxyimide compound as the precursor alcohol of the general formula (5B) is obtained.

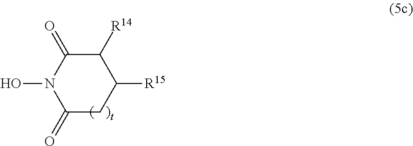

In the formula (5c), R¹⁴ and R¹⁵ are each independently a hydrogen atom or a C₁-C₁₀ straight, C₃-C₁₀ branched or C₃-C₁₀ cyclic hydrocarbon group; a carbon atom of the hydrocarbon group may be replaced by an oxygen atom; R¹⁴ and R¹⁵ may be bonded together to form a ring structure; and t is an integer of 0 to 2.

Specific examples of the alcohol of the general formula (5B) are fluorine-containing N-sulfonyloxyimides indicated below.

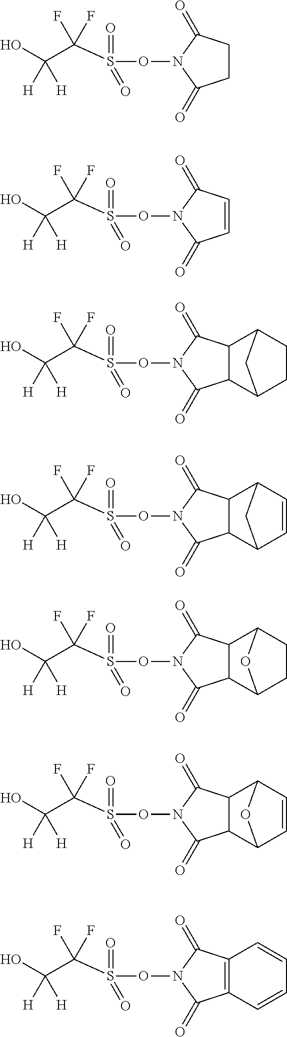

The following groups are examples of the group of the general formula (5) introduced into the silicon compound of the general formula (1) with the use of the above fluorine-containing N-sulfonyloxyimides.

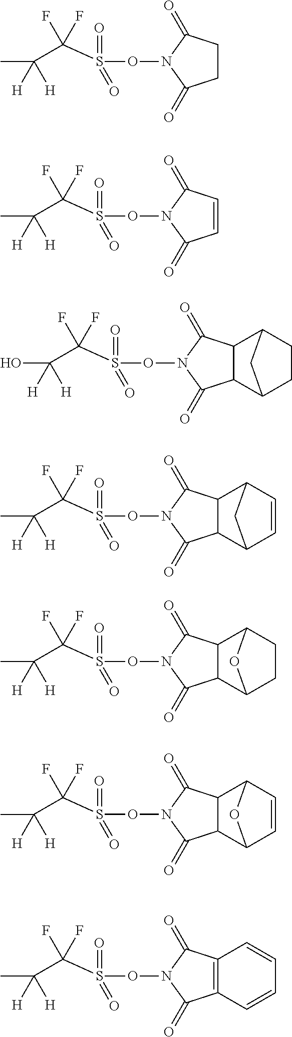

2.3.2 Case of Containing Group of General Formula (6) as Group (A) in Silicon Compound of General Formula (1)

The following explanation will be given on the case where the group A is the group of the general formula (6) in the silicon compound of the general formula (1).

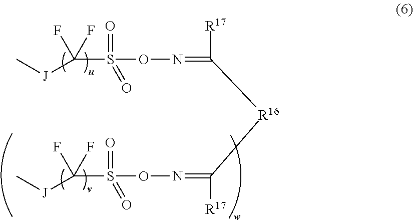

In the formula (6), R¹⁶ is a single bond or a hydrocarbon group selected from the group consisting of a C₁-C₂₀ alkylene group and a C₆-C₁₅ arylene group; a carbon atom of the hydrocarbon group may be replaced by an oxygen atom; R¹⁷ is each independently a methyl group, a trifluoromethyl group, a perfluoroethyl group, a perfluoropropyl group, a 5H-perfluoropentyl group (—(CF₂)₄—CF₂H), a 6H-perfluorohexyl group (—(CF₂)₅—CF₂H), a cyano group or a nitro group; u is an integer of 1 to 2; v is an integer of 1 to 2; w is 0 or 1; when w is 0, R¹⁷ may be bonded together to form a ring structure; and J is a single bond or a divalent organic group which may have an ester bond, an urethane bond or an amide bond.

[Synthesis of Precursor Alcohol]

An alcohol compound of the following general formula (6A) is an example of a precursor alcohol for introduction of the group of the general formula (6) as the group A into the silicon compound of the general formula (1).

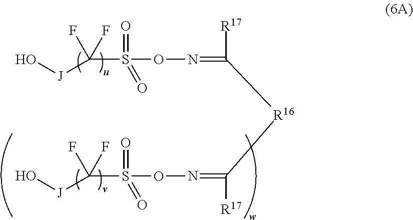

In the formula (6A), R¹⁶ is a single bond or a hydrocarbon group selected from the group consisting of a C₁-C₂₀ alkylene group and a C₆-C₁₅ arylene group; a carbon atom of the hydrocarbon group may be replaced by an oxygen atom; R¹⁷ is each independently a methyl group, a trifluoromethyl group, a perfluoroethyl group, a perfluoropropyl group, a 5H-perfluoropentyl group (—(CF₂)₄—CF₂H), a 6H-perfluorohexyl group (—(CF₂)₅—CF₂H), a cyano group or a nitro group; u is an integer of 1 to 2; v is an integer of 1 to 2; w is 0 or 1; when w is 0, R¹⁷ may be bonded together to form a ring structure; and J is a single bond or a divalent organic group which may have an ester bond, an urethane bond or an amide bond.

By way of example, the process for synthesis of a precursor alcohol of the general formula (6B), which is one example of the alcohol compound of the general formula (6A), will be explained below. The following reaction scheme shows synthesis of the alcohol of the general formula (6B) as one synthesis example. It is however noted that the precursor alcohol is not limited to the alcohol of the general formula (6B).

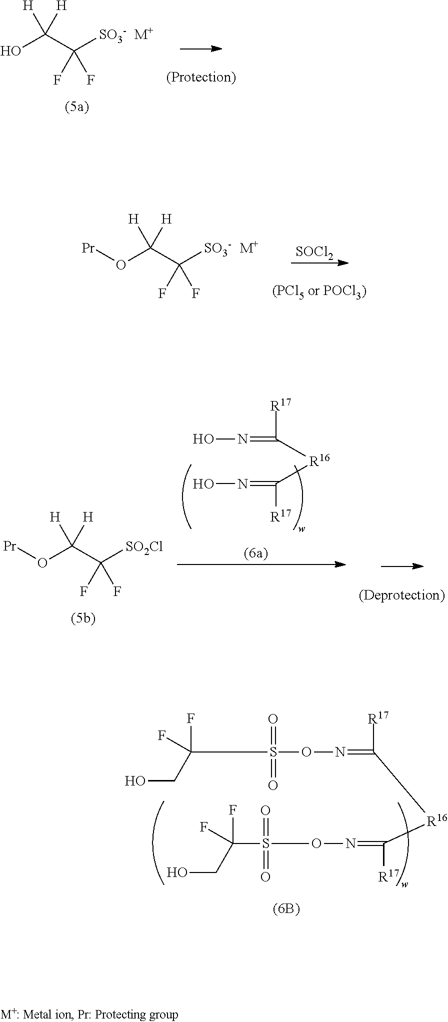

In this synthesis process, a sulfonyl chloride of the formula (5b) synthesized as described above with reference to Patent Documents 5 and 6 is reacted with an oxime of the general formula (6a) synthesized from a ketone and a hydroxylamine.

Namely, the oxime of the general formula (6a) and the sulfonyl chloride of the formula (5) are dissolved in a solvent such as THF, dichloromethane etc. and reacted with each other under basic conditions, or are reacted in a basic solvent such as triethylamine, pyridine etc. With this, the target alcohol of the general formula (6B) is obtained.

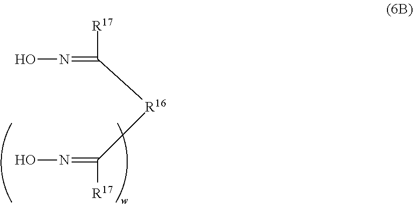

In the formula (6B), R¹⁶ is a single bond or a hydrocarbon group selected from the group consisting of a C₁-C₂₀ alkylene group and a C₆-C₁₅ arylene group; a carbon atom of the hydrocarbon group may be replaced by an oxygen atom; R¹⁷ is each independently a methyl group, a trifluoromethyl group, a perfluoroethyl group, a perfluoropropyl group, a 5H-perfluoropentyl group, a 6H-perfluorohexyl group, a cyano group or a nitro group; w is 0 or 1; when w is 0, R¹⁷ may be bonded together to form a ring structure; and J is a single bond or a divalent organic group which may have an ester bond, an urethane bond or an amide bond.

In this case, R¹⁷ is preferably a cyano group or trifluoromethyl group. Further, w is preferably 0. When w is 0, R¹⁶ is preferably any of the following groups.

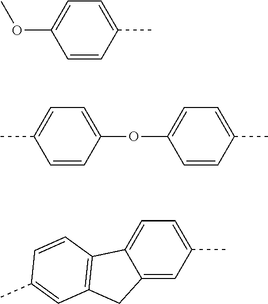

3. Production Method of Silicon Compound of General Formula (1)

A production method of the silicon compound of the general formula (1) will be described below by way of specific example. In the following reaction schemes, each of L and Q is a linking group; and the other groups are those defined above.

The synthesis of a silicon compound of the general formula (2A) will be first explained below with reference to the following reaction scheme. The target silicon compound of the general formula (2A) can be obtained by reaction of an alkoxysilane derivative of the general formula (1A) with an alcohol of the general formula (4A) in the absence of a catalyst, in the presence of a base catalyst or under non-catalytic conditions.

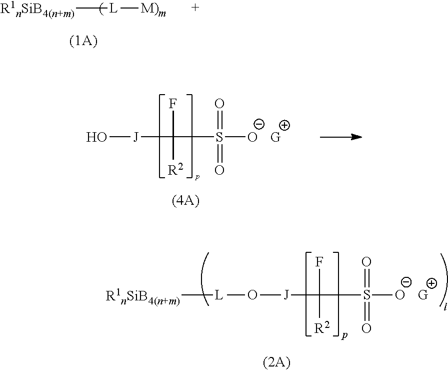

There is no particular limitation on the amount of the alcohol of the general formula (4A) reacted with the silicon compound precursor of the general formula (1A). The amount of the alcohol is generally 0.1 to 10 mol, preferably 0.2 to 5 mol, per 1 mol of the silicon compound precursor.

The addition reaction can be performed in the presence or absence of a solvent. In general, an aprotic solvent is used as the reaction solvent. Examples of the aprotic solvent are diisopropyl ether, dichloroethane, chloroform, toluene, ethylbenzene, monochlorobenzene and acetonitrile. These solvents can be used solely or in combination of two or more thereof

There is no particular limitation on the reaction temperature. The reaction temperature is generally in a range of 0 to 200° C., preferably 0 to 50° C. Preferably, the reaction is performed by stirring.

Although the reaction time is varied depending on the reaction temperature, the reaction time is generally several minutes to 100 hours, preferably 30 minutes to 50 hours, more preferably 1 to 20 hours. It is preferable to determine the time at which the silicon compound precursor has been consumed as the end of the reaction while monitoring the progress of the reaction by any analytical means such as nuclear magnetic resonance (NMR). The reaction can preferably be performed without the use of a catalyst in a basic solvent such as triethylamine or pyridine.

When the solvent is removed under a reduced pressure, the target silicon-containing compound of the general formula (2A) to which the photoacid generator has been introduced is obtained in the form of a polymerizable fluorine-containing sulfonic acid onium salt. This silicon-containing compound can be purified by ordinary means such as extraction or recrystallization after the completion of the reaction.

The synthesis of a silicon compound of the general formula (2B) will be next explained below with reference to the following reaction scheme. The target silicon compound of the general formula (2B) can be obtained by addition or condensation reaction between a silicon compound precursor of the general formula (1B) and a carboxylic acid of the general formula (4B). The addition reaction takes place on an epoxy group or oxetanyl group, so as to form a hydroxyl group-containing ester bond. The condensation reaction takes place on an amino group, so as to form an amide bond. It is feasible to perform each of the addition reaction and the condensation reaction in the same manner as the synthesis reaction of the silicon compound of the general formula (2A).

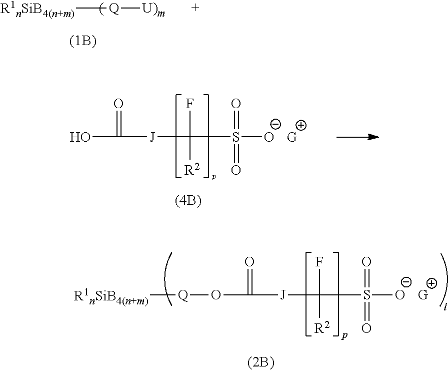

The synthesis of silicon compounds of the general formulas (2C) to (2E), (5C) and (6C) as preferred examples of the silicon compound of the general formula (1) in the present invention will be further explained below with reference to the following reaction schemes.

The silicon-containing carboxylic acid salt of the general formula (2C), the silicon-containing methide acid onium salt of the general formula (2D), the silicon-containing sulfoneamide onium salt of the general formula (2E), the silicon-containing N-sulfonyloxyimide compound of the general formula (5C) and the silicon-containing oximesulfonate compound of the general formula (6C) can be obtained in the above-mentioned method from the corresponding alcohols of the general formulas (4C), (4D), (4E), (5A) and (6A), respectively.

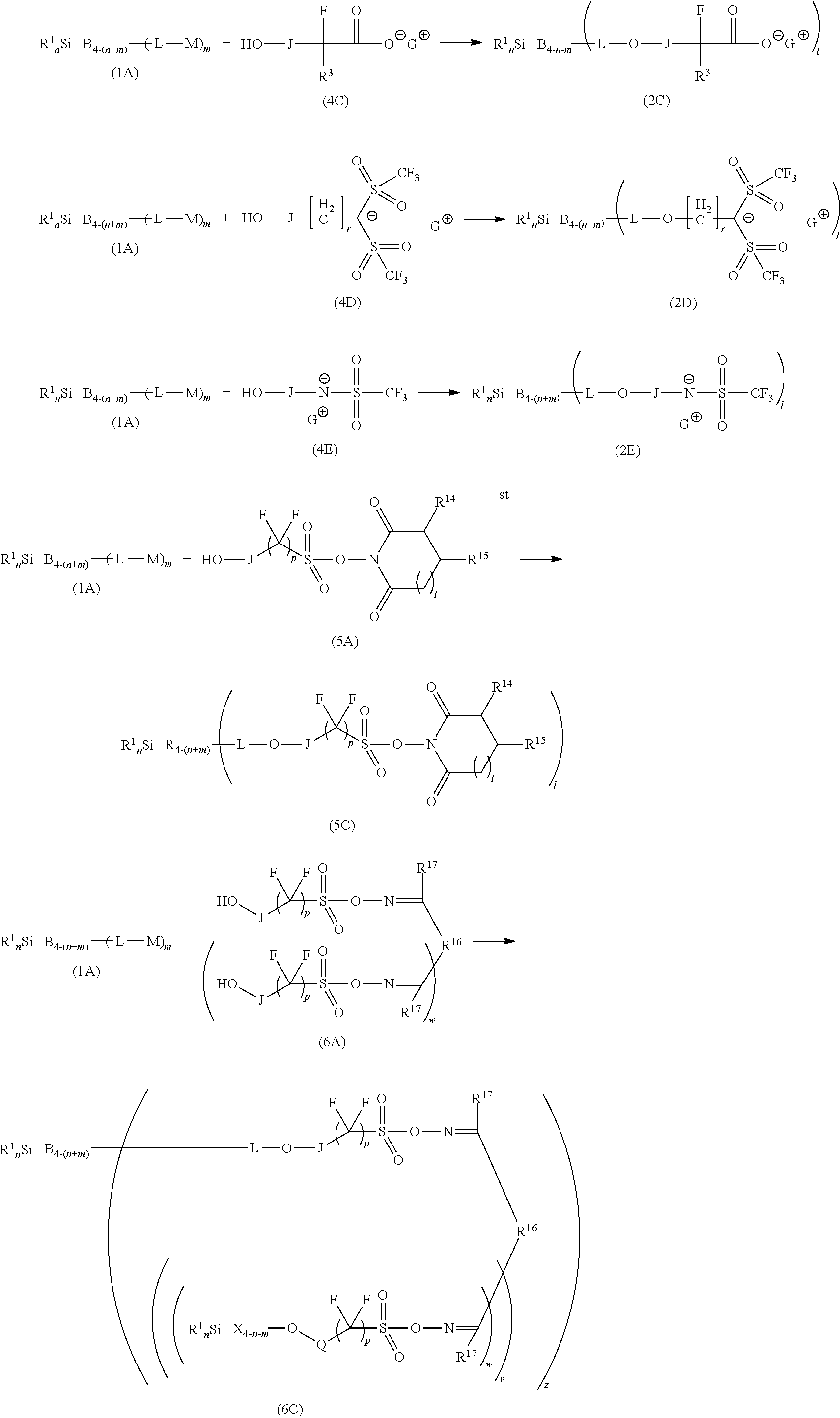

More specifically, the silicon compounds of the general formulas (2C) to (2E), (5C) and (6C) are synthesized by reaction of the hydroxyfluoroalkanesulfonic acid onium salt of the general formula (4A), the carboxyfluoroalkanesulfonyl acid onium salt of the general formula (4B), the hydroxyfluorocarboxylic acid onium salt of the general formula (4C), the hydroxymethide acid onium salt of the general formula (4D), the hydroxysulfoneamide salt of the general formula (4E), the N-sulfonyloxyimide-containing alcohol of the general formula (5A) and the oximesulfonate-containing alcohol of the general formula (6A) as the photoacid generating moiety-containing group, that is, the precursor of the group (A) in the general formula (1) with the silicon compound of the general formula (1A) or (1B). In other words, the addition reaction takes place between the alcohol of the general formula (4A) and the precursor compound of the general formula (1A). In this reaction, a hydroxyl group-containing ester bond is formed when the group M is an epoxy group or oxetanyl group. On the other hand, an urethane bond is formed when the reaction takes place on an isocyanate group.

[Precursor Compound and Target Silicon Compound]

Next, the precursor compounds of the general formulas (4A) to (4E), (5A) and (6A) and the target silicon compounds of the general formulas (2A) to (2E), (5C) and (6C) will be explained in detail below.

Specific examples of the hydroxyfluoroalkanesulfonic acid onium salt as the precursor compound of the general formula (4A) are 2-hydroxy-1,1-difluoroethanesulfonic acid triphenylsulfonium, 4-hydroxy-1,1,2,2-tetrafluorobutanesulfonic acid triphenylsulfonium, 5-hydroxy-1,1,2,2-tetrafluoropentanesulfonic acid triphenylsulfonium and 6-hydroxy-1,1,2,2-tetrafluorohexanesulfonic acid triphenylsulfonium. These compounds can be synthesized as described in Patent Documents 5 to 9.

Specific examples of the carboxylfluoroalkanesulfonic acid onium salt as the precursor compound of the general formula (4B) are 2,2-difluoro-3-hydroxypentanoic acid triphenylsulfonium, 2-fluoro-2-trifluoromethyl-3-hydroxypentanoic acid triphenylsulfonium and 2-fluoro-2-pentafluoroethyl-3-hydroxypentanoic acid triphenylsulfonium. These compounds can be synthesized as described in Patent Document 11. More specifically, it is feasible to synthesize the target carboxylfluoroalkanesulfonic acid onium salt of the general formula (4B) by hydrolyzing the 2-fluoro-3-hydroxypentanoic acid alkyl ester derivative under basic or acidic conditions and reacting the resulting 2,2-difluoro-3-hydroxypentanoic acid with triphenylsulfonyl bromide or triphenylsulfonyl chloride.

Specific examples of the hydroxyfluorocarboxylic acid onium salt as the precursor compound of the general formula (4C) are triphenylsulfonium hydroxycarbonyldifluoromethanesulfonate and the like. These compounds can be synthesized as described in Patent Document 11.

Specific examples of the hydroxymethide acid onium salt as the precursor compound of the general formula (4D) are 3-hydroxy-1,1-bis(trifluoromethanesulfonyl)butane, 3-hydroxy-1,1-bis(trifluoromethanesulfonyl)propane and 3-hydroxy-1,1-bis(heptafluoromethanesulfonyl)butane. These compounds can be synthesized as described in Patent Document 11.

Specific examples of the hydroxysulfone amide salt as the precursor compound of the general formula (4E) are trifluorophenylsulfonium salt of trifluoromethanesulfonic acid amide ethanol. As one specific synthesis process, it is feasible to obtain the trifluorophenylsulfonium salt of trifluoromethanesulfonic acid amide ethanol by converting trifluoromethanesulfonic acid amide ethanol to a sodium salt thereof in an aqueous sodium hydroxide solution and reacting the sodium salt with triphenylsulfonyl bromide. As the fluorine-containing alkyl group other than trifluoromethyl group, there can be used a pentafluoroethyl group or nonafluoropropyl group.

The hydroxy-N-sulfonyloxyimide compound as the precursor compound of the general formula (5A) and the hydroxyl-oximesulfonate compound as the precursor compound of the general formula (6A) can be synthesized as described above.

In the silicon compounds of the general formulas (1A) and (1B), the linking groups L and Q are each a methylene group, a divalent alicyclic hydrocarbon group, a divalent aromatic group, a divalent heterocyclic group or the like. Hydrogen atoms of these linking groups may be substituted with a fluorine atom. Each of these linking group may be bonded with at least one group selected from the group consisting of an etheric oxygen atom, an etheric sulfur atom, a carbonyl group, an ester group, an oxycarbonyl group, an amide group, a sulfoneamide group, an urethane group and an urea group to form a divalent linking group. All or part of hydrogen atoms bonded to carbon atoms of the divalent linking group may be substituted with a fluorine atom. The divalent linking group may have a ring structure.

In the general formula (1A), the group M is any group capable of reacting with a hydroxyl group. There can be used an epoxy group, an oxetanyl group or an isocyanate group as the group M. Examples of the group M are 3-glycidoxypropyltrimethoxysilane, 3-glycidoxypropyltriethoxysilane, 5,6-epoxyhexyltrimethoxysilane, 5,6-epoxyhexyltriethoxysilane, 2-(3,4-epoxycyclohexyl)ethyltrimethoxysilane, 2-(3,4-epoxycyclohexyl)ethyltriethoxysilane, 3-oxetanylpropyltrimethoxysilane, 3-oxetanylpropyltriethoxysilane and 3-iso cyanatepropyltriethoxysilane.

In the general formula (1B), the group U is any group capable of reacting with a carboxyl group. There can be used an epoxy group, an oxetanyl group or an amino group as the group U. Examples of the group U are 3-glycidoxypropyltrimethoxysilane, 3-glycidoxypropyltriethoxysilane, 5,6-epoxyhexyltrimethoxysilane, 5,6-epoxyhexyltriethoxysilane, 2-(3,4-epoxycyclohexyl)ethyltrimethoxysilane, 2-(3,4-epoxycyclohexyl)ethyltriethoxysilane, 3-oxetanylpropyltrimethoxysilane, 3-oxetanylpropyltriethoxysilane, N-2-(aminoethyl)-3-aminopropylmethyldimethoxysilane, N-2-(aminoethyl)-3-aminopropylmethyltrimethoxysilane, N-2-(aminoethyl)-3-aminopropylmethyltriethoxysilane, 3-aminopropylmethyltrimethoxysilane, 3-aminopropylmethyltriethoxysilane and N-phenyl-3-aminopropyltrimethoxysilane.

Examples of the hydrolysable group in the general formulas (1A) and (1B) are an alkoxy group, a halogen atom, an acetoxy group, an isocyanate group and a hydroxyl group. Among others, an alkoxy group is preferred in terms of solution stability and application properties. There can suitably be used a methoxy group, an ethoxy group, a propoxy group or the like.

4. Production Method of Condensation Product from Silicon Compound of General Formula (1)

A silicon resin as a condensation product according to the present invention can be produced by any ordinary alkoxysilane hydrolysis/condensation reaction process without particular limitation. For example, it is feasible to obtain the silicon resin as the condensation product by placing each of the silicon compounds of the general formula (2A) to (2E), (5C) and (6C) as examples of the silicon compound of the general formula (1) into a reactor at room temperature (20C.°), feeding water for hydrolysis of the silicon compound, an acid catalyst for condensation of the silicon compound and a reaction solvent into the reactor, heating the resulting reaction solution with stirring and thereby conducting hydrolysis and condensation of the silicon compound.

At this time, a reflux condenser is preferably attached to the reactor so as to reflux the reaction solution and prevent evaporation of the unreacted raw material, water, acid and reaction solvent from the reaction system. The time required for the condensation reaction is generally 3 to 5 hours. The reaction temperature is generally 50 to 100° C. After the completion of the reaction, the reaction solution is returned to room temperature (20 C.°) and subjected to contact extraction with a water-immiscible organic solvent in order to extract the condensation product from the reaction system. The resulting extract is washed with water to remove the acid therefrom.

The reaction solvent is preferably an alcohol. Examples of the alcohol as the reaction solvent are ethanol, n-propanol, isopropanol and butanol. Examples of the water-immiscible organic solvent used to extract the condensation product from the reaction system after the condensation reaction are organic solvents immiscible with water and capable of dissolving therein the condensation product, such as ethers e.g. diethyl ether, isopropyl ether and dibutyl ether, chlorinated solvents e.g. chloroform and dichloromethane and ethyl acetate. In particular, ethers are preferred.

The condensation product is obtained by removing a slight amount water dissolved in the extract with the use of a solid drying agent, and then, removing the organic solvent under a reduced pressure. Herein, magnesium sulfate, calcium sulfate, synthetic zeolite etc. can be used as the solid drying agent.

For production of the condensation product, the amount of water used in the hydrolysis and condensation is 1.5 to 5 times molar equivalent of alkoxy group contained in the total alkoxysilane raw material. If the amount of water is less than 1.5 times molar equivalent, the hydrolysis does not proceed efficiently so that the resulting condensation product may deteriorate in storage stability. It is not necessary that the amount of water exceeds 5 times molar equivalent in view of difficulty in handling.

In the synthesis of the condensation product, the silicon compound of the general formula (1) may be copolymerized with another dialkoxysilane, trialkoxysilane or tetraalkoxysilane in order to control the properties of the condensation product.

Examples of the dialkoxysilane are dimethyldimethoxysilane, dimethyldiethoxysilane, dimethyldipropoxysilane, dimethyldiphenoxysilane, diethyldimethoxysilane, diethyldiethoxysilane, diethyldipropoxysilane, diethyldiphenoxysilane, dipropyldimethoxysilane, dipropyldiethoxysilane, diphenyldimethoxysilane, diphenyldiethoxysilane, diphenyldiphenoxysilane, bis(3,3,3-trifluoropropyl)dimethoxysilane and methyl(3,3,3-trifluoropropyl)dimethoxysilane.

Examples of trialkoxyslane are methyltrimethoxysilane, ethyltrimethoxysilane, propyltrimethoxysilane, isopropyltrimethoxysilane, phenyltrimethoxysilane, methyltriethoxysilane, ethyltriethoxysilane, propyltriethoxysilane, isopropyltriethoxysilane, phenyltriethoxysilane, methyltripropoxysilane, ethyltripropoxysilane, propyltripropoxysilane, isopropyltripropoxysilane, phenyltripropoxysilane, methyltriisopropoxysilane, ethyltriisopropoxysilane, propyltriisopropoxysilane, isopropyltriisopropoxysilane, phenyltriisopropoxysilane, trifluoromethyltrimethoxysilane, pentafluoroethyltrimethoxysilane, 3,3,3-trifluoropropyltrimethoxysilane and 3,3,3-trifluoropropyltriethoxysilane.

Examples of the tetraalkoxysilane are tetramethoxysilane, tetraethoxysilane, tetrapropoxysilane and tetraisopropoxysilane.

The above dialkoxysilane, trialkoxysilane or tetraalkoxysilane can be used solely or in combination of two or more kinds thereof.

5. Pattern Formation Method

A photosensitive composition according to the present invention is obtained by dissolving the condensation product in an organic solvent B in which the condensation product is soluble. A pattern formation method according to the present invention includes a first step of applying a film of the photosensitive composition to a substrate and drying the film, a second step of exposing the film to a high-energy ray through a photomask of predetermined pattern and a third step of processing the film into a resist pattern by dissolving an unexposed portion of the film with a developer and thereby transferring the pattern of the photomask to the film.

In the photosensitive composition, the organic solvent B is preferably a polar solvent capable of dissolving therein the condensation product. Examples of the polar solvent are propylene glycol monomethyl ether acetate (abbreviated as PGMEA), propylene glycol monomethyl ether, cyclohexanone, γ-butyrolactone, ethyl lactate, methyl ethyl ketone, methyl isobutyl ketone, N,N-dimethylformamide and N-methylpyrrolidone.

Although the photoacid generating group has been introduced to the silicon compound of the general formula (1), a photoacid generator may be added separately to the photoresist composition as needed in order to obtain a fine pattern. Examples of the photoacid generator are triphenylsulfonium trifluoromethanesulfonates. These triphenylsulfonium trifluoromethanesulfonates are commercially available under the product names of Irgacure PAG121, Irgacure PAG103, Irgacure CGI1380 and Irgacure CGI725 from U.S. BASF Corporation, under the product names of PAI-101, PAI-106, NAI-105, NAI-106, TAZ-110 and TAX-204 from Midori Kagaku Co., Ltd., under the product names of CPI-200K, CPI-210S, CPI-101A, CPI-110A, CPI-100P, CPI-110P, CPI-100TF, HS-1, HS-1A, HS-1P, HS-1N, HS-1TF, HS-1NF, HS-1MS, HS-1CS, LW-S1, LW-S1NF from San-Apro Ltd., and under the product names of TFE-triazine, TME-triazine and MP-triazine from Sanwa Chemical Co., Ltd.

The photosensitive composition according to the present invention is in liquid form and is thus applied by a wet process to the substrate such as glass substrate or silicon substrate. The applied composition is prebaked, i.e., preheated to remove the organic solvent B. The resulting resist film is processed into a negative resist pattern by lithography.

More specifically, the resist film is irradiated with the high-energy ray through the photomask so as to induce further condensation of the condensation product by generation of the acid from the photoacid generating group in the irradiated resist film portion and thereby make the irradiated resist film portion insoluble in the developer. The resist film is then developed with the developer to dissolve the unexposed portion in the developer so that the irradiated resist film portion remains as the negative resist pattern on the substrate.

The thus-obtained negative resist pattern is heat baked so as to induce further condensation of silanol group remaining in the pattern. The heat baking is preferably performed at a high temperature in order to obtain a high-hardness thin film. The upper limit of the heating temperature is varied depending on the usage such as semiconductor, display or the like. For example, the upper limit of the heating temperature is 250° C. when the thin film is used as an overcoat protecting film for formation of a pattern of polyimide in an ordinary liquid crystal display

There can be used an aqueous solution of tetramethylammonium hydroxide as the developer for formation of the negative resist pattern from the composition according to the present invention.

Further, there can be used an ultraviolet ray, an electromagnetic wave of 400 nm or less wavelength such as g ray (wavelength: 436 nm), h ray (wavelength: 405 nm) or i ray (wavelength: 365 nm) from high-pressure mercury lamp, a KrF excimer laser ray (wavelength: 248 nm), a ArF excimer laser ray (wavelength: 193 nm), an extreme ultraviolet ray (wavelength: 13.5 nm) or an electron beam as the high-energy ray in the pattern formation method for formation of the negative resist pattern from the composition according to the present invention.

6. Applicability

The silicon compound and its condensation product according to the present invention are applicable to not only resists but also protecting films and insulating films for displays e.g. liquid crystal displays, touch panels and organic EL (electro luminescence) displays, hard masks and various insulating films for use in semiconductor manufacturing processes, permanent films etc.

### EXAMPLES

Hereinafter, the present invention will be described in more detail below by way of the following examples. It should be noted that the following examples are illustrative and are not intended to limit the present invention thereto.

As examples of the silicon compound of the general formula (1) according to the present invention, alkoxysilanes (1) to (5) each having a hydrolysable group and a photoacid generating group were synthesized. Subsequently, condensation products (1) to (15) were produced by hydrolysis and condensation of the alkoxysilanes (1) to (5) with other alkoxysilanes. Each of these condensation products (1) to (15) was dissolved in a solvent, followed by applying a film of the resulting composition to a substrate and subjecting the film to lithographic patterning (Examples 1-15). The same operations were performed except that condensation products (Comparative Examples 1-3) were produced without the use of any alkoxysilane containing hydrolysable and photoacid generating groups as the silicon-containing compound according to the present invention.

More specifically, the alkoxysilanes (1) to (5) with the respective hydrolysable groups and photoacid generating groups were synthesized by the following procedures.

1. Synthesis of Alkoxysilanes (1) to (5)

[Synthesis of Alkoxysilane (1)]

In a 100-mL three-neck flask, 3.01 g of the following isocyanate-containing alkoxysilane (a), 5 g of the following alcohol compound (a) as a precursor of a photoacid generating group and 20 g of acetonitrile as a solvent were placed. The resulting reaction solution was reacted by stirring for 3 hours at room temperature (about 20° C.), followed by distilled the solvent from the reaction solution under a reduced pressure. The thus-obtained high viscosity solution was analyzed by IR spectrum measurement. The reaction product had an urethane bond due to the presence of an absorption peak of NH group at around 3300 cm⁻¹ and an absorption peak of carbonyl (═C═O) group at around 1650 cm⁻¹ in the spectrum. The reaction product was thus determined to be alkoxysilane (1).

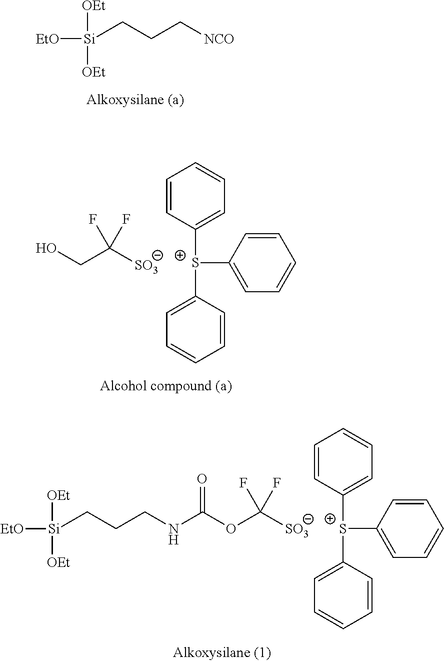

[Synthesis of Alkoxysilane (2)]

In a 100-mL three-neck flask, 2.43 g of the following glycidyl-containing alkoxysilane (b), 5 g of the following carboxylic acid compound (b) as a precursor of a photoacid generating group and 20 g of acetonitrile were placed. The resulting reaction solution was reacted by stirring for 3 hours at room temperature (about 20° C.), followed by distilling the solvent from the reaction solution under a reduced pressure. The thus-obtained high viscosity solution was analyzed by IR spectrum measurement. The reaction product had an ester bond due to the presence of an absorption peak of ester bond in the spectrum. The reaction product was thus determined to be alkoxysilane (2).

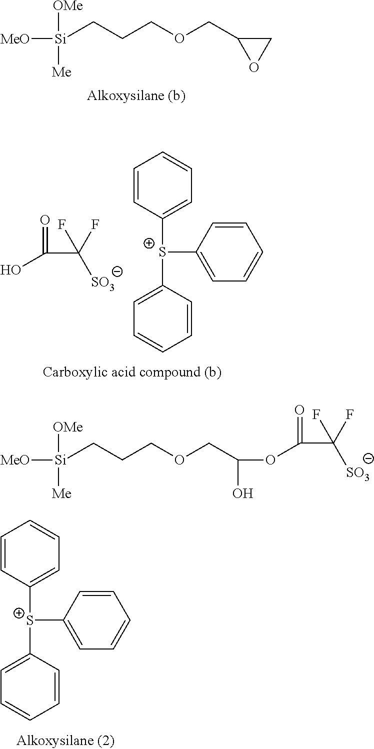

[Synthesis of Alkoxysilane (3)]

In a 100-mL three-neck flask, 1.98 g of the following amino-containing alkoxysilane (c), 5 g of the following carboxylic acid compound (c) as a precursor of a photoacid generating group and 20 g of acetonitrile were placed The resulting reaction solution was reacted by stirring for 3 hours at 150° C., followed by distilling the solvent from the reaction solution under a reduced pressure. The thus-obtained high viscosity solution was analyzed by IR spectrum measurement. The reaction product had an amide bond due to the presence of an absorption peak of amide bond at around 1650 cm⁻¹ in the spectrum. The reaction product was thus determined to be alkoxysilane (3).

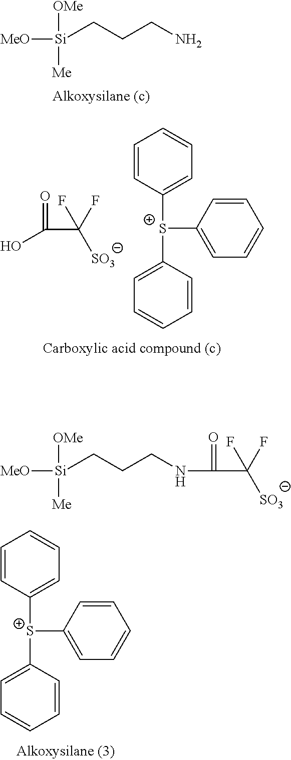

[Synthesis of Alkoxysilane (4)]

In a 100-mL three-neck flask, 2.06 g of the following isocyanate-containing alkoxysilane (d), 5 g of the following alcohol compound (d) as a precursor of a photoacid generating group and 20 g of acetonitrile were placed. The resulting reaction solution was reacted by stirring for 3 hours at room temperature (about 20° C.), followed by distilling the solvent from the reaction solution under a reduced pressure. The thus-obtained high viscosity solution was analyzed by IR spectrum measurement. The reaction product had an urethane bond due to the presence of an absorption peak of NH group at around 3300 cm⁻¹ and an absorption peak of ═C═O group at around 1650 cm⁻¹ in the spectrum. The reaction product was thus determined to be alkoxysilane (4).

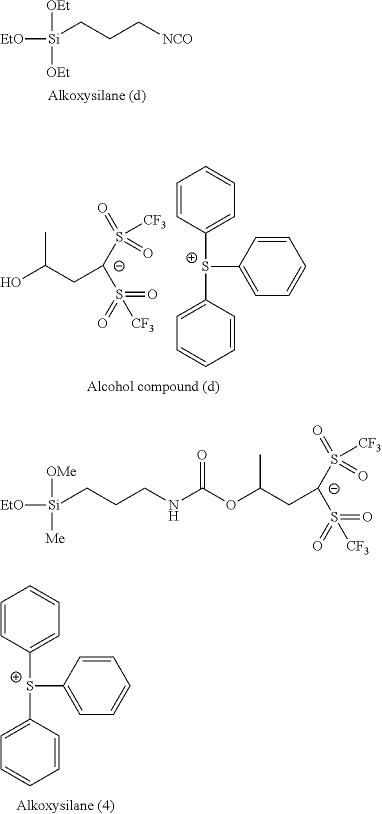

[Synthesis of Alkoxysilane (5)]

In a 100-mL three-neck flask, 2.97 g of the following isocyanate-containing alkoxysilane (e), 5 g of the following alcohol compound (3) as a precursor of the photoacid generating group and 20 g of acetonitrile were placed. The resulting reaction solution was reacted by stirring for 3 hours at room temperature (about 20° C.), followed by distilling the solvent from the reaction solution under a reduced pressure. The thus-obtained high viscosity solution was analyzed by IR spectrum measurement. The reaction product had an urethane bond due to the presence of an absorption peak of NH group at around 3300 cm⁻¹ and an absorption peak of ═C═O group at around 1650 cm⁻¹ in the spectrum. The reaction product was thus determined to be alkoxysilane (5).

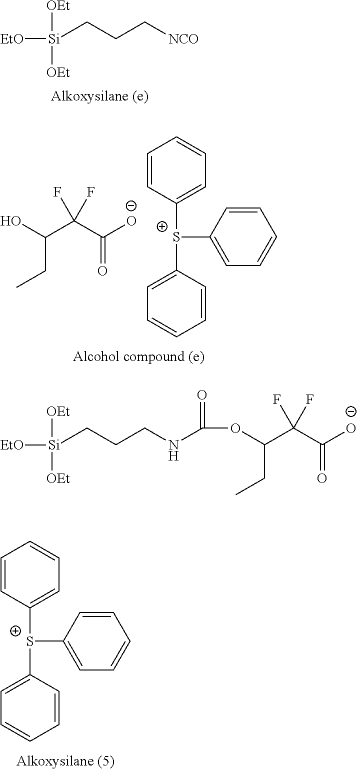

2. Production of Condensation Products (1) to (15)

The condensation products (1) to (15) were produced by hydrolysis and condensation of the above-synthesized alkoxysilanes (1) to (5) with other alkoxysilanes by the following procedures. Hereinafter, phenyl, methyl and ethyl are sometimes abbreviated as Ph, Me and Et, respectively.

### Example 1

### Production of Condensation Product (1)

In a three-neck flask with an impeller stirrer and a reflux condenser, total 30 g of a mixture of the alkoxysilane (1), tetraethoxysilane (abbreviated as “TEOS”), PhSi(OEt)₃ and Me₂Si(OEt)₂ was placed in such a manner that the molar feed ratios of the alkoxysilane (1), TEOS, PhSi(OEt)₃ and Me₂Si(OEt)₂ were 5 mol %, 10 mol %, 55 mol % and 30 mol %, respectively. Further, 150 g of isopropanol and 110 g of water as a solvent and 0.10 g of acetic acid as a hydrolysis catalyst were placed in the three-neck flask.

The resulting reaction system in the three-neck flask was subjected to hydrolysis and condensation reaction by heating at 90° C. After a lapse of 3 hours, the reaction solution was returned to room temperature. Upon addition of 200 ml of isopropyl ether and 200 ml of water into the three-neck flask, the reaction solution was stirred and thereby divided into two phases. The upper phase of the reaction solution was recovered and washed three times each with 200 ml of water. The washed solution was dehydrated by adding magnesium sulfate. Then, the solvent was removed from the dehydrated solution with an evaporator. There was thus obtained condensation product (1) as a viscous liquid. The condensation product (1) had a weight-average molecular weight (Mw) of 1050. The weight-average molecular weight was determined in terms of polystyrene by GPC measurement using THF solvent. Unless otherwise specified, the weight-average molecular weight was determined in the same manner as above in the following examples.

### Examples 2 to 15

### Production of Condensation Products (2) to (15)

The condensation products (2) to (15) were obtained by hydrolysis and condensation of the alkoxysilanes (1) to (5) with other alkoxysilanes in the same manner as in Example 1.

The feed ratios (molar ratios) of the alkoxysilanes and the measurement results of the weight-average molecular weights (Mw) are indicated in TABLE 1.

TABLE 1

| | | | Molecular |
|---|---|---|---|
| Exam- | Condensation | Composition | weight |
| ple | product | Feed ratio (molar ratio) | Mw |
| 1 | 1 | alkoxysilane (1):TEOS:PhSi(OEt)₃:Me₂Si(OEt)₂ | 1050 |
| | | 5:10:55:30 | |
| 2 | 2 | alkoxysilane (1):MeSi(OEt)₃:Ph₂Si(OEt)₂ | 900 |
| | | 3:57:40 | |
| 3 | 3 | alkoxysilane (1):PhSi(OEt)₃:MeSi(OEt)₃:Me₂Si(OEt)₂ | 1150 |
| | | 5:40:25:30 | |
| 4 | 4 | alkoxysilane (2):TEOS:PhSi(OEt)₃:Me₂Si(OEt)₂ | 1080 |
| | | 5:10:55:30 | |
| 5 | 5 | alkoxysilane (2):MeSi(OEt)₃:Ph₂Si(OEt)₂ | 880 |
| | | 3:57:40 | |
| 6 | 6 | alkoxysilane (2):PhSi(OEt)₃:Me₂Si(OEt)₂ | 1200 |
| | | 5:70:25 | |
| 7 | 7 | alkoxysilane (3):TEOS:PhSi(OEt)₃:Me₂Si(OEt)₂ | 980 |
| | | 5:10:55:30 | |
| 8 | 8 | alkoxysilane (3):MeSi(OEt)₃:Ph₂Si(OEt)₂ | 950 |
| | | 3:57:40 | |
| 9 | 9 | alkoxysilane (3):PhSi(OEt)₃:MeSi(OEt)₃:Me₂Si(OEt)₂ | 1200 |
| | | 5:40:25:30 | |
| 10 | 10 | alkoxysilane (4):TEOS:PhSi(OEt)₃:Me₂Si(OEt)₂ | 930 |
| | | 5:10:55:30 | |
| 11 | 11 | alkoxysilane (4):MeSi(OEt)₃:Ph₂Si(OEt)₂ | 1120 |
| | | 3:57:40 | |
| 12 | 12 | alkoxysilane (4):PhSi(OEt)₃:MeSi(OEt)₃:Me₂Si(OEt)₂ | 1050 |
| | | 5:40:25:30 | |
| 13 | 13 | alkoxysilane (5):TEOS:PhSi(OEt)₃:Me₂Si(OEt)₂ | 1030 |
| | | 5:10:55:30 | |
| 14 | 14 | alkoxysilane (5):MeSi(OEt)₃:Ph₂Si(OEt)₂ | 980 |
| | | 3:57:40 | |
| 15 | 15 | alkoxysilane (5):PhSi(OEt)₃:MeSi(OEt)₃:Me₂Si(OEt)₂ | 1250 |
| | | 5:40:25:30 | |

### Comparative Example 1

In a three-neck flask with an impeller stirrer and a reflux condenser, total 30 g of a mixture of n-butyltriethoxysilane, TEOS, PhSi(OEt)₃ and Me₂Si(OEt)₂ was placed in such a manner that the molar feed ratios of the n-butyltriethoxysilane, TEOS, PhSi(OEt)₃ and Me₂Si(OEt)₂ were 30 mol %, 10 mol %, 30 mol % and 30 mol %, respectively. Further, 150 g of isopropanol and 110 g of water as a solvent and 0.10 g of acetic acid as a hydrolysis catalyst were placed in the three-neck flask. The resulting reaction solution was subjected to hydrolysis and condensation reaction by heating at 90° C. After a lapse of 3 hours, the reaction solution was returned to room temperature (20° C.). Upon addition of 200 ml of isopropyl ether and 200 ml of water into the three-neck flask, the reaction solution was stirred and thereby divided into two phases. The upper phase of the reaction solution was recovered and washed three times each with 200 ml of water. The washed solution was dehydrated by adding magnesium sulfate. Then, the solvent was removed from the dehydrated solution with an evaporator. There was thus obtained a condensation product in viscous liquid form. The condensation product had a weight-average molecular weight (Mw) of 910.

### Comparative Examples 2 and 3

### Production of Condensation Products (17) and (18)

Siloxane condensation products (17) and (18) were produced in the same manner as in Comparative Example 1.

The feed ratios (molar ratios) of the alkoxysilanes and the measurement results of the weight-average molecular weights (Mw) are indicated in TABLE 2.

TABLE 2

| Comparative | Condensation | Composition | Molecular |
|---|---|---|---|
| Example | product | Feed ratio (molar ratio) | weight Mw |
| 1 | 16 | nBuSi(OEt)₃:TEOS:PhSi(OEt)₃:Me₂Si(OEt)₂ | 910 |
| | | 30:10:30:30 | |
| 2 | 17 | nPr₂Si(OMe)₂:MeSi(OEt)₃:Ph₂Si(OEt)₂ | 1020 |
| | | 20:60:20 | |
| 3 | 18 | nBuSi(OMe)₃:PhSi(OEt)₃:Me₂Si(OEt)₂ | 1050 |
| | | 30:30:40 | |

3. Pattern Formation

In 9.00 g of propylene glycol monomethyl ether acetate (abbreviated as “PGMEA”), 3.00 g of each of the condensation products (1) to (15) according to the present invention as listed in TABLE 1 was dissolved. The resulting solution was applied by spin coating to a silicon wafer and heated at 110° C. for 1 minute, thereby obtaining a coating film with a thickness of 2 to 3 μm. The coating film was exposed through a photomask to an ultraviolet ray of 248 nm wavelength, close to KrF excimer laser wavelength. Subsequently, the exposed coating film was heated at 120° C. for 3 minutes and developed by dissolving an unexposed portion of the coating film in 2.38 mass % aqueous tetramethylammonium hydroxide solution. The developed coating film was washed with water of room temperature (20° C.) and then heated at 250° C. for 1 hour. In this way, a negative resist pattern was obtained on the silicon wafer by transferring the pattern of the photomask to the coating film. It was confirmed by observation of the pattern that the shape of the pattern was desired rectangular shape and satisfactory.

In 9.00 g of PGMEA as a solvent, 2.95 g of each of the condensation products (16) to (18) out of the scope of the present invention as listed in TABLE 2 and 0.05 g of triphenylsulfonium.trifluoromethylsulfonate (CF₃SO₃⁻.Ph₃S⁺) as a photoacid generator were dissolved. The resulting solution was evaluated for patterning performance by lithography in the same manner as above. The results are indicated in TABLE 3.

TABLE 3

| Comparative | Condensation | Pattern |
|---|---|---|
| Example | product | shape |
| 1 | 16 | head-swollen shape |
| 2 | 17 | distorted shape |
| 3 | 18 | distorted shape |

In the case of using each of the condensation products of Examples (1) to (15), the shape of the pattern was fine rectangular shape. In the case of using the condensation products of Comparative Examples (1) to (3), by contrast, the shape of the pattern was head-swollen shape or distorted shape. It has been shown by these results that the resist composition containing the condensation product with the photoacid generating group according to the present invention has advantage over the conventional resist compositions.

1. A silicon compound of the general formula (1):
R¹ₙAₘSiB₄₋₍ₙ₊ₘ₎ (1)
where R¹ is each independently a hydrogen atom, a C₁-C₂₀ straight or C₃-C₂₀ branched or cyclic hydrocarbon group; a carbon atom of the hydrocarbon group may be replaced by an oxygen atom; and the hydrocarbon group may contain a fluorine atom; A is an acid decomposable group; B is a hydrolysable group; n is an integer of 0 to 2; m is an integer of 1 to 3; and n+m is an integer of 1 to 3.

2. The silicon compound according to claim 1, wherein at least one of A is a group of the general formula (2-1):
-D-E^{⊖} (2-1)
where D is a single bond or a divalent organic group which may have an ester bond, an urethane bond or an amide bond; and E⁻ is a group of the general formula (3-1), a group of the general formula (3-2), a group of the general formula (3-3) or a group of the general formula (3-4): 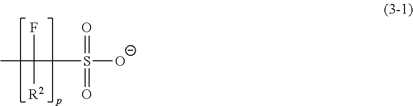
where R² is each independently a fluorine atom or a C₁-C₁₀ fluorine-containing alkyl group; and p is an integer of 1 to 2, 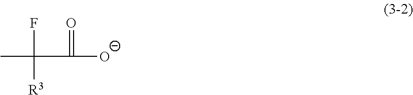
where R³ is each independently a fluorine atom or a C₁-C₁₀ fluorine-containing alkyl group, 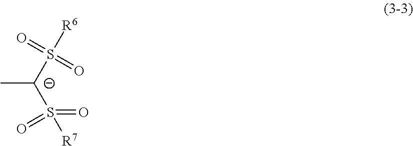
where R⁶ and R⁷ are each independently a C₁-C₁₀ fluorine-containing alkyl group, 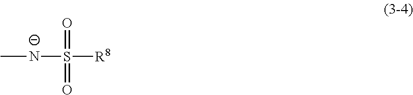
where R⁸ is a C₁-C₁₀ fluorine-containing alkyl group.

3. The silicon compound according to claim 1, wherein at least one of A is a group of the formula (2-1):
-D-E^{⊖} (2-1)
where D is a single bond or a divalent organic group which may have an ester bond, an urethane bond or an amide bond; and E⁻ is a group of the formula (3-5), a group of the formula (3-6), a group of the formula (3-7) or a group of the formula (3-8): 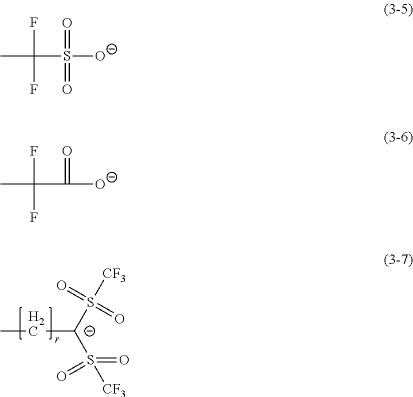
where r is an integer of 1 to 3

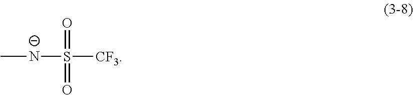

4. The silicon compound according to claim 1, wherein at least one of A is a group of the general formula (2-2):
-D-E^{⊖}G^{⊕} (2-2)
where D is a single bond or a divalent group which may have an ester bond, an urethane bond or an amide group;
E⁻ is a group of the general formula (3-1), a group of the general formula (3-2), a group of the general formula (3-3), a group of the general formula (3-4), a group of the formula (3-5), a group of the formula (3-6), a group of the formula (3-7) or a group of the formula (3-8): 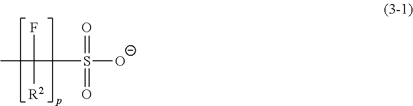
where R² is each independently a fluorine atom or a C₁-C₁₀ fluorine-containing alkyl group; and p is an integer of 1 to 2; 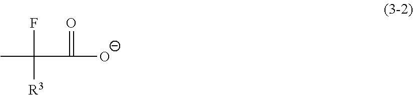
where R³ is a fluorine atom or a C₁-C₁₀ fluorine-containing alkyl group; 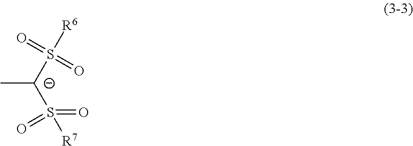
where R⁶ and R⁷ are each independently a C₁-C₁₀ fluorine-containing alkyl group; 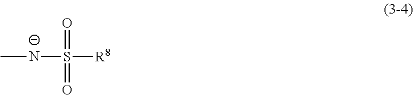
where R⁸ is a C₁-C₁₀ fluorine-containing alkyl group; 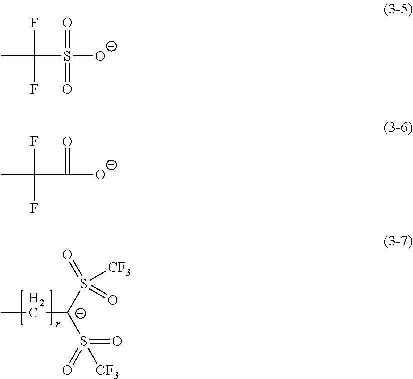
where r is an integer of 1 to 3 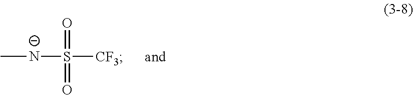
G⁺ is a sulfonium cation of the formula (4-1) or a iodonium cation of the formula (4-2); 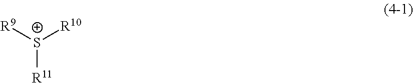
where R⁹, R¹⁰ and R¹¹ are each independently a hydrocarbon group selected from the group consisting of a C₁-C₂₀ straight or C₃-C₂₀ branched or cyclic alkyl group, a C₁-C₂₀ straight or C₃-C₂₀ branched or cyclic alkenyl group, a C₆-C₂₀ aryl group and a C₇-C₂₀ aralkyl group; a carbon atom of the hydrocarbon group may be replaced by an oxygen atom; and two or more of R⁹, R¹⁰ and R¹¹ may be bonded together to form a ring structure, 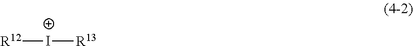
where R¹² and R¹³ are each independently a hydrocarbon group selected from the group consisting of a C₁-C₂₀ straight or C₃-C₂₀ branched or cyclic alkyl group, a C₁-C₂₀ straight or C₃-C₂₀ branched or cyclic alkenyl group, a C₆-C₂₀ aryl group and a C₇-C₂₀ aralkyl group; a carbon atom of the hydrocarbon group may be replaced by an oxygen atom; and R¹² and R¹³ may be bonded together to form a ring structure.

5. The silicon compound according to claim 1, wherein at least one of A is a group of the general formula (5): 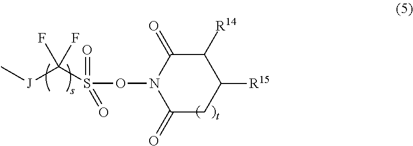
where R¹⁴ and R¹⁵ are each independently a hydrogen atom or a C₁-C₁₀ straight, C₃-C₁₀ branched or C₃-C₁₀ cyclic hydrocarbon group; a carbon atom of the hydrocarbon group may be replaced by an oxygen atom; R¹⁴ and R¹⁵ may be bonded together to form a ring structure; J is a single bond or a divalent group which may have an ester bond, an urethane bond or an amide group; s is an integer of 1 to 2; and t is an integer of 0 to 2.

6. The silicon compound according to claim 1, wherein at least one of A is a group of the general formula (6): 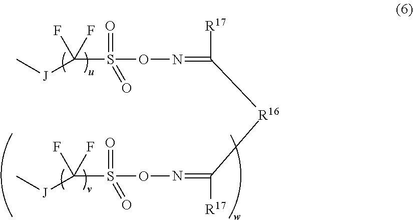
where R¹⁶ is a single bond or a hydrocarbon group selected from the group consisting of a C₁-C₂₀ alkylene group and a C₆-C₁₅ arylene group; a carbon atom of the hydrocarbon group may be replaced by an oxygen atom; R¹⁷ is each independently a methyl group, a trifluoromethyl group, a perfluoroethyl group, a perfluoropropyl group, a 5H-perfluoropentyl group, a 6H-perfluorohexyl group, a cyano group or a nitro group; u is an integer of 1 to 2; v is an integer of 1 to 2; w is 0 or 1; when w is 0, R¹⁷ may be bonded together to form a ring structure; and J is a single bond or a divalent organic group which may have an ester bond, an urethane bond or an amide bond.

7. A condensation product obtained by condensation of the silicon compound according to claim 1.

8. A composition comprising the condensation product according to claim 7 and a solvent.

9. A pattern formation method, comprising:
a first step of forming a film by applying the composition according to claim 8 to a substrate and drying the applied composition;
a second step of exposing the film to a high-energy ray through a photomask of predetermined pattern; and
a third step of forming a resist pattern by dissolving an exposed unexposed portion of the film with a developer and thereby transferring the pattern of the photomask to the film.
